(19) United States
(12) Patent Application Publication
(10) Pub. No.: US 2025/0228089 A1
(43) Pub. Date: Jul. 10, 2025

(54) DISPLAY DEVICE AND ELECTRONIC DEVICE INCLUDING THE SAME

(71) Applicant: SAMSUNG DISPLAY CO., LTD., Yongin-Si (KR)

(72) Inventors: SOOHONG CHEON, Yongin-si (KR); KYUNG-HO PARK, Yongin-si (KR); JONGMIN LEE, Yongin-si (KR)

(21) Appl. No.: 19/000,349

(22) Filed: Dec. 23, 2024

(30) Foreign Application Priority Data
Jan. 9, 2024 (KR) 10-2024-0003304

(51) Int. Cl. H10K 59/131; H10K 59/121

(52) U.S. Cl. CPC H10K 59/131; H10K 59/1213

(57) ABSTRACT

A display device includes: a first active pattern disposed on a substrate; a gate electrode disposed on the first active pattern and including a body part and a protrusion part, wherein the body part overlaps the first active pattern in a plan view, and the protrusion part protrudes from the body part in a first direction; a lower electrode disposed below the first active pattern and having a first side adjacent to an end of the protrusion part in a second direction opposite to the first direction; and a first connection pattern disposed on the gate electrode, and in contact with the first active pattern, wherein the first connection pattern covers the first side of the lower electrode.

### CROSS-REFERENCE TO RELATED APPLICATION

This application claims priority under 35 U.S.C. § 119 to Korean Patent Application No. 10-2024-0003304, filed on Jan. 9, 2024, the disclosure of which is incorporated by reference herein in its entirety.

### TECHNICAL FIELD

Embodiments of the present invention relate to a display device. More specifically, embodiments of the present invention relate to a display device which provides visual information.

### DISCUSSION OF THE RELATED ART

As information technology develops, the importance of a display device as a connection medium between a user and information increases. For example, the use of display devices such as a liquid crystal display device (LCD), an organic light emitting display device (OLED), a plasma display device (PDP), a quantum dot display device and the like is increasing.

Generally, a display device includes a plurality of pixels, and each pixel typically includes a transistor, a capacitor, and a light emitting element. The transistor, the capacitor and the light emitting element are formed from conductive layers.

### SUMMARY

According to an embodiment of the present invention, a display device includes: a first active pattern disposed on a substrate; a gate electrode disposed on the first active pattern and including a body part and a protrusion part, wherein the body part overlaps the first active pattern in a plan view, and the protrusion part protrudes from the body part in a first direction; a lower electrode disposed below the first active pattern and having a first side adjacent to an end of the protrusion part in a second direction opposite to the first direction; and a first connection pattern disposed on the gate electrode, and in contact with the first active pattern, wherein the first connection pattern covers the first side of the lower electrode.

In an embodiment of the present invention, in a plan view, the first connection pattern overlaps at least a portion of the protrusion part and is spaced apart from at least a portion of the protrusion part.

In an embodiment of the present invention, an upper surface of the gate electrode has a first step due to the lower electrode, an upper surface of the insulating layer between the gate electrode and the first connection pattern has a second step due to the first step of the upper surface of the gate electrode, and an upper surface of the first connection pattern has a third step due to the second step of the upper surface of the insulating layer.

In an embodiment of the present invention, the first connection pattern covers a portion of the insulating layer where the second step is formed.

In an embodiment of the present invention, the first step of the upper surface of the gate electrode is formed in the body part of the gate electrode.

In an embodiment of the present invention, the first connection pattern has a second side adjacent to the end of the protrusion part, and the second side is closer to the end of the protrusion part than the first side of the lower electrode.

In an embodiment of the present invention, in a plan view, the shortest distance in the second direction from the end of the protrusion part to the first side of the lower electrode is greater than the shortest distance in the second direction from the end of the protrusion part to the second side of the first connection pattern.

In an embodiment of the present invention, in a plan view, the second side of the first connection pattern is spaced apart from the first side of the lower electrode in the first direction.

In an embodiment of the present invention, the lower electrode is spaced apart from the protrusion part in a plan view.

In an embodiment of the present invention, the display device further includes: a first transistor and a second transistor electrically connected to each other, and wherein the first transistor includes the first active pattern and at least a portion of the gate electrode.

In an embodiment of the present invention, the display device further includes: a second active pattern spaced apart from the first active pattern; and a gate line spaced apart from the gate electrode and disposed on the second active pattern, and wherein the second transistor includes the second active pattern and at least a portion of the gate line.

In an embodiment of the present invention, the protrusion part protrudes toward the second active pattern.

In an embodiment of the present invention, the display device further includes: a second connection pattern connected the protrusion part and the second active pattern, and wherein the second active pattern and the gate electrode are electrically connected to each other through the second connection pattern.

In an embodiment of the present invention, the display device further includes: a data line disposed on the substrate and electrically connected to the second active pattern; and a third connection pattern connected to the second active pattern and the data line.

In an embodiment of the present invention, the display device further includes: a storage capacitor electrically connected to the first transistor, and wherein the storage capacitor includes at least a portion of the lower electrode and at least a portion of the gate electrode.

In an embodiment of the present invention, the second transistor is a switching transistor which transmits a data voltage based on a switching operation, and the first transistor is a driving transistor which generates a driving current corresponding to the data voltage.

In an embodiment of the present invention, the protrusion part and the body part are a single body.

According to an embodiment of the present invention, a display device includes: a display panel including a plurality of sub-pixels; a gate driver providing a gate signal to the display panel; and a data driver providing a data voltage to the display panel, and wherein each of the sub-pixels includes a first transistor, a second transistor, and a storage capacitor which are electrically connected to each other, the first transistor includes a first active pattern and at least a portion of a gate electrode disposed on the first active pattern, the second transistor includes a second active pattern and at least a portion of a gate line disposed on the second active pattern, wherein the second active pattern is spaced apart from the first active pattern, the storage capacitor includes at least a portion of a lower electrode and at least a portion of the gate electrode, wherein the lower electrode is disposed below the first active pattern, and the gate electrode includes a body part and a protrusion part, wherein the body part overlaps the first active pattern in a plan view, and the protrusion part protrudes from the body part in a first direction and is spaced apart from the lower electrode in a plan view.

In an embodiment of the present invention, the display device further includes: a first connection pattern disposed on the gate electrode and connected to the first active pattern; and a second connection pattern disposed on a same layer as the first connection pattern and connected to the protrusion part and the second active pattern, and wherein the first connection pattern overlaps at least a portion of the protrusion part and is spaced apart from at least a portion of the protrusion part, and wherein the second active pattern and the gate electrode are electrically connected to each other through the second connection pattern.

In an embodiment of the present invention, the second transistor is a switching transistor which transmits a data voltage that is provided from the data driver based on a switching operation, and the first transistor is a driving transistor which generates a driving current corresponding to the data voltage.

According to an embodiment of the present invention, an electronic device includes: a display device and a processor which controls the display device, the display device includes: a first active pattern disposed on a substrate, a gate electrode disposed on the first active pattern and including a body part and a protrusion part, wherein the body part overlaps the first active pattern in a plan view, and the protrusion part protrudes from the body part in a first direction, a lower electrode disposed below the first active pattern and having a first side adjacent to an end of the protrusion part in a second direction opposite to the first direction, and a first connection pattern disposed on the gate electrode, and in contact with the first active pattern, wherein the first connection pattern covers the first side of the lower electrode.

### BRIEF DESCRIPTION OF THE DRAWINGS

The above and other features of the present invention will become more apparent by describing in detail embodiments thereof, with reference to the accompanying drawings, in which:

FIG. 1 is a plan view illustrating a display device according to an embodiment of the present invention.

FIG. 2 is a block diagram illustrating the display device of FIG. 1.

FIG. 3 is a circuit diagram of a sub-pixel included in the display device of FIG. 1.

FIGS. 4, 5, 6, 7, 8, 9, 10, 11 and 12 are layout views illustrating a pixel included in the display device of FIG. 1.

FIG. 13 is an enlarged view of area A of FIG. 10.

FIG. 14 is a cross-sectional view taken along line I-I′ of FIG. 13.

FIG. 15 is a cross-sectional view illustrating the display device of FIG. 1.

FIG. 16 is a block diagram illustrating an electronic device according to an embodiment of the present disclosure.

### DETAILED DESCRIPTION OF THE EMBODIMENTS

Regarding embodiments of the present invention disclosed herein, structural and functional descriptions are merely illustrative for a purpose of explaining the embodiments of the present invention, and the embodiments of the present invention may be implemented in various forms. Accordingly, the present invention is not to be construed as being limited to the embodiments described herein.

Terms such as first, second, etc. may be used to describe various components, but the components should not be limited by the terms. The above terms may be used for the purpose of distinguishing one component from another component. For example, a first component may be referred to as a second component, and similarly, a second component may be referred to as a first component without departing from the spirit and scope of the present invention.

Hereinafter, display devices in accordance with embodiments of the present invention will be described in more detail with reference to the accompanying drawings. The same reference numerals are used for the same components in the drawings and the specification, and redundant descriptions of the same components may be omitted or briefly described.

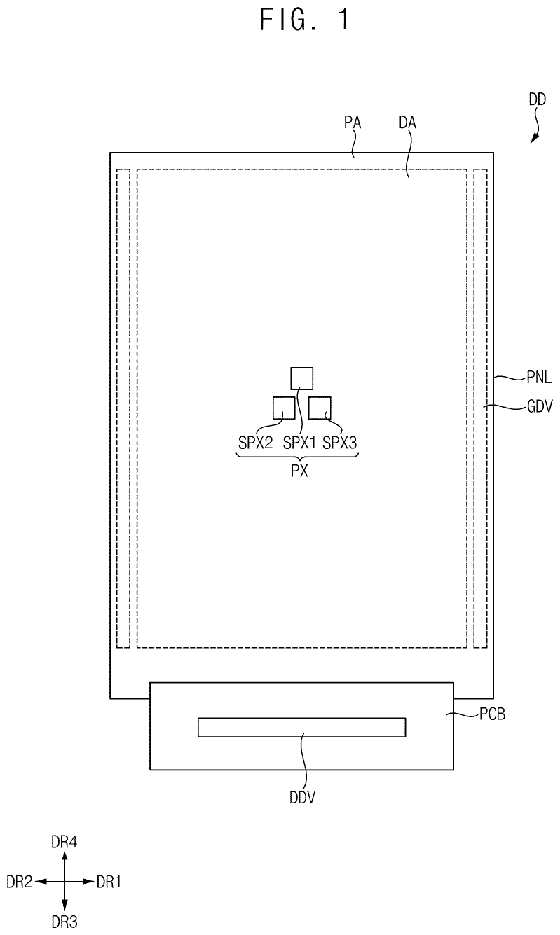

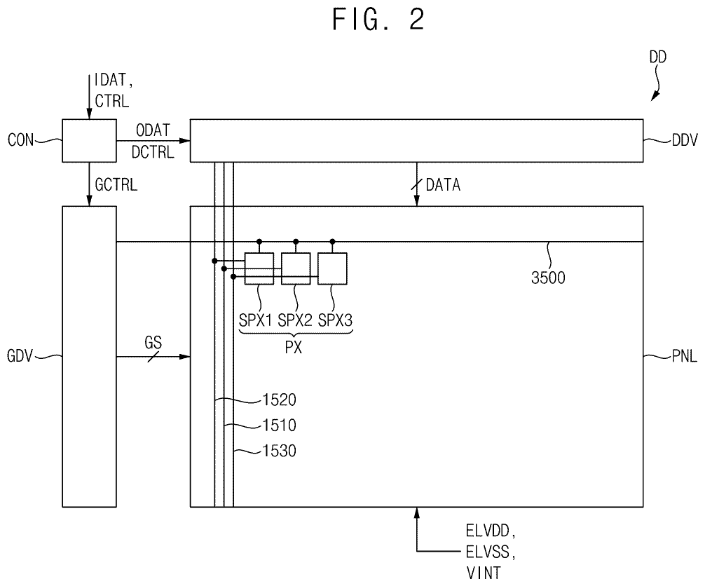

FIG. 1 is a plan view illustrating a display device according to an embodiment of the present invention, and FIG. 2 is a block diagram illustrating the display device of FIG. 1.

Referring to FIGS. 1 and 2, a display device DD according to an embodiment of the present invention may be divided into a display area DA and a peripheral area PA. The display area DA may display an image, and the peripheral area PA may be located around the display area DA. For example, the peripheral area PA may at least partially surround the display area DA.

The display device DD may include a display panel PNL, a data driver DDV, a gate driver GDV, and a controller CON.

The display panel PNL may include a plurality of pixels. For example, the pixels may be arranged in a matrix form along a first direction DR1, a second direction DR2 opposite to the first direction DR1, a third direction DR3 crossing the first direction DR1, and a fourth direction DR4 opposite to the third direction DR3.

Each of the pixels may include a plurality of sub-pixels. For example, the pixel PX may include a first sub-pixel SPX1, a second sub-pixel SPX2, and a third sub-pixel SPX3. Each of the first sub-pixel SPX1, the second sub-pixel SPX2, and the third sub-pixel SPX3 may receive a data voltage DATA, a gate signal GS, a driving voltage ELVDD, a common voltage ELVSS, and an initialization voltage VINT.

In an embodiment of the present invention, the second sub-pixel SPX2 may receive the data voltage DATA through a first data line 1510 and receive the gate signal GS through a gate line 3500. The first sub-pixel SPX1 may receive the data voltage DATA through a second data line 1520 and the gate signal GS through the gate line 3500. The third sub-pixel SPX3 may receive the data voltage DATA through a third data line 1530 and the gate signal GS through the gate line 3500.

The data driver DDV may generate the data voltage DATA based on output image data ODAT and data control signal DCTRL. For example, the data driver DDV may generate the data voltage DATA corresponding to the output image data ODAT and output the data voltage DATA in response to the data control signal DCTRL. The data control signal DCTRL may include an output data enable signal, a horizontal start signal, and a load signal.

In an embodiment of the present invention, the data driver DDV may be connected to the display panel PNL through a printed circuit board PCB. For example, the data driver DDV may be implemented with a plurality of chips, and each of the chips may be attached to a printed circuit board PCB. However, the present invention is not necessarily limited thereto. For example, the data driver DDV may be integrated inside the display panel PNL.

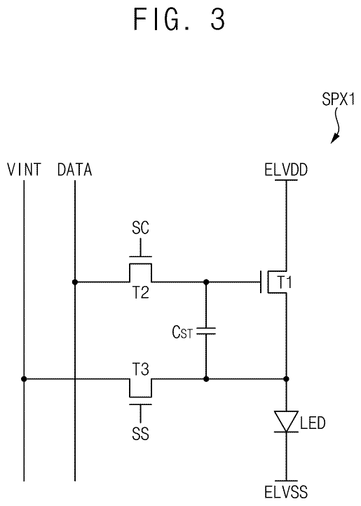

The gate driver GDV may generate the gate signal GS based on the gate control signal GCTRL. The gate signal GS may include a first scan signal and a second scan signal, which will be described later with reference to FIG. 3. For example, each of the first scan signal and the second scan signal may include a gate-on voltage, which turns on a transistor, and a gate-off voltage, which turns off the transistor. The gate control signal GCTRL may include, for example, a vertical start signal, a clock signal, or the like.

In an embodiment of the present invention, the gate driver GDV may be integrated on both sides of the display panel PNL. For example, the gate driver GDV may be integrated on a left side and a right side of the display panel PNL. Accordingly, a response speed of the display panel PNL may be increased. However, the present invention is not necessarily limited thereto. For example, the gate driver GDV may be connected to the display panel PNL through a printed circuit board.

The controller CON (e.g., a timing controller) may receive input image data IDAT and control signal CTRL from an external host processor. For example, the input image data IDAT may be RGB data including red image data, green image data, and blue image data. The control signal CTRL may include, for example, a vertical synchronization signal, a horizontal synchronization signal, an input data enable signal, and a master clock signal. The controller CON may generate the gate control signal GCTRL, the data control signal DCTRL, and the output image data ODAT based on the input image data IDAT and the control signal CTRL.

FIG. 3 is a circuit diagram of a sub-pixel included in the display device of FIG. 1.

Specifically, FIG. 3 is a circuit diagram of the first sub-pixel SPX1 included in the display device DD. The second sub-pixel SPX2 and the third sub-pixel SPX3 may have substantially the same circuit structure as the first sub-pixel SPX1.

Referring to FIG. 3, the first sub-pixel SPX1 may include a first transistor T1, a second transistor T2, a third transistor T3, a storage capacitor CST, and a light emitting element LED.

The first transistor T1 may include a first terminal, a second terminal, and a gate terminal. The first terminal of the first transistor T1 may receive the driving voltage ELVDD. The second terminal of the first transistor T1 may be connected to the light emitting element LED. The gate terminal of the first transistor T1 may be connected to the second transistor T2. The first transistor T1 may be a driving transistor which generates a driving current corresponding to the data voltage DATA. For example, the first transistor T1 may generate the driving current based on the driving voltage ELVDD and the data voltage DATA.

The second transistor T2 may include a first terminal, a second terminal, and a gate terminal. The first terminal of the second transistor T2 may receive the data voltage DATA. The second terminal of the second transistor T2 may be connected to the first transistor T1. The gate terminal of the second transistor T2 may receive a first scan signal SC. The second transistor T2 may be a switching transistor which transmits the data voltage DATA based on a switching operation. For example, the second transistor T2 may transmit the data voltage DATA in response to the first scan signal SC.

The third transistor T3 may include a first terminal, a second terminal, and a gate terminal. The first terminal of the third transistor T3 may be connected to the first transistor T1. The second terminal of the third transistor T3 may receive the initialization voltage VINT. The gate terminal of the third transistor T3 may receive a second scan signal SS. The third transistor T3 may transmit the initialization voltage VINT in response to the second scan signal SS.

The storage capacitor CST may include a first terminal and a second terminal. The first terminal of the storage capacitor CST may be connected to the gate terminal of the first transistor T1. The second terminal of the storage capacitor CST may be connected to the first terminal of the third transistor T3. The storage capacitor CST may maintain a voltage level of the gate terminal of the first transistor T1 during a deactivation period of the first scan signal SC.

The light emitting element LED may include a first terminal and a second terminal. The first terminal of the light emitting element LED may be connected to the second terminal of the first transistor T1. The second terminal of the light emitting element LED may receive the common voltage ELVSS. The light emitting element LED may emit light with luminance corresponding to the driving current. The light emitting element LED may include an organic light emitting element using an organic material as a light emitting layer, an inorganic light emitting element using an inorganic material as a light emitting layer, or the like.

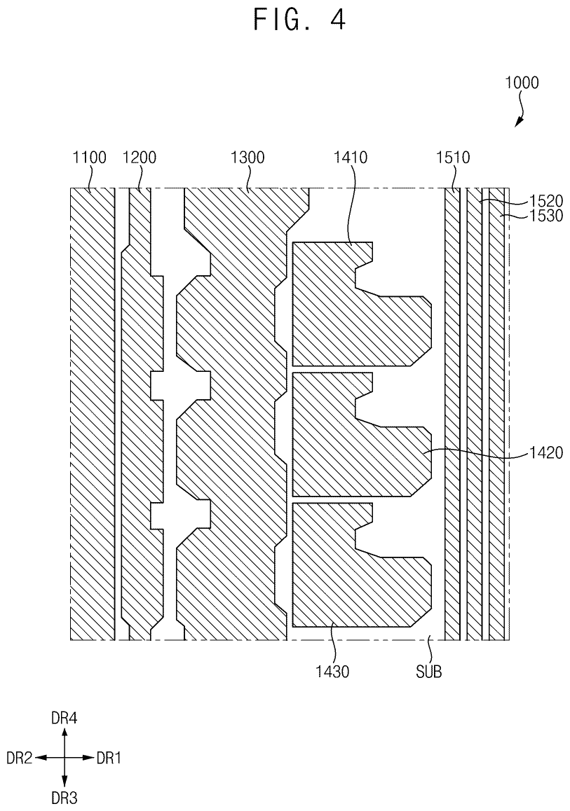

FIGS. 4 to 12 are layout views illustrating a pixel included in the display device of FIG. 1.

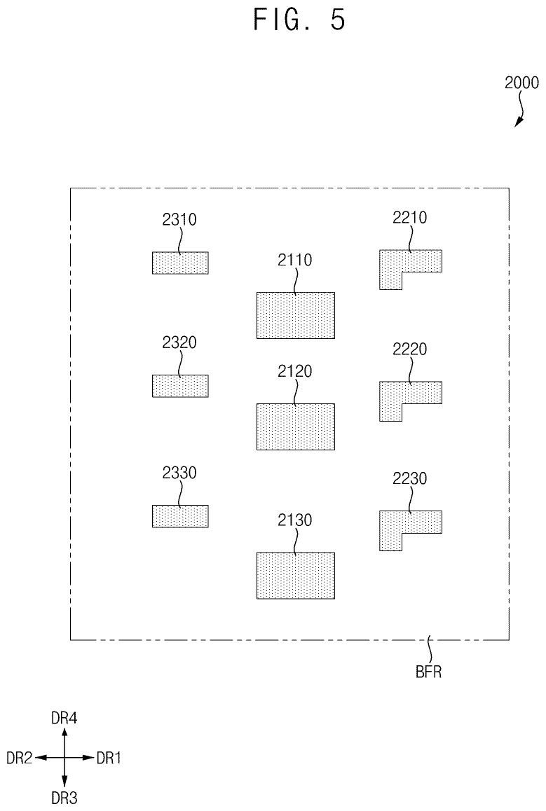

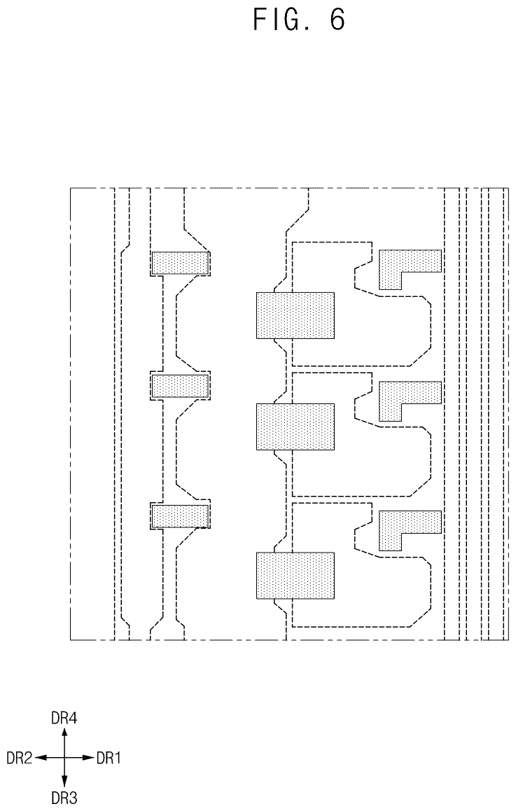

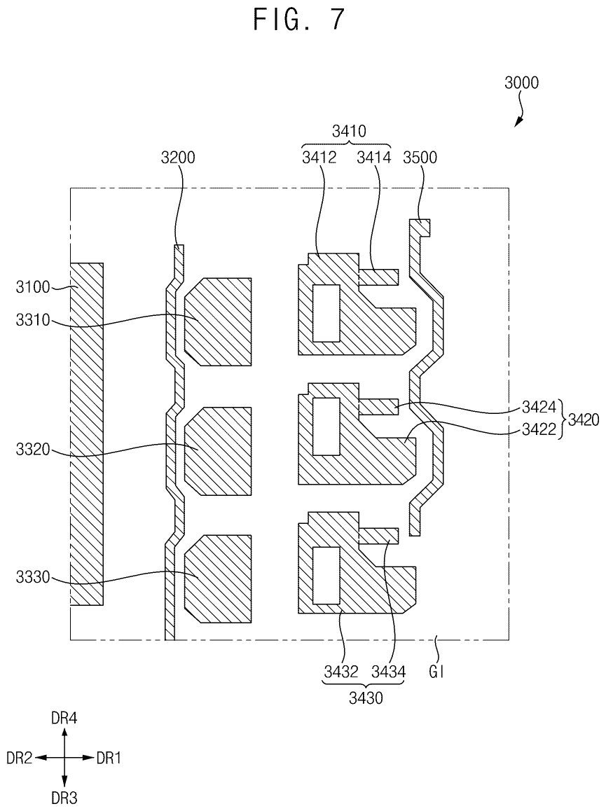

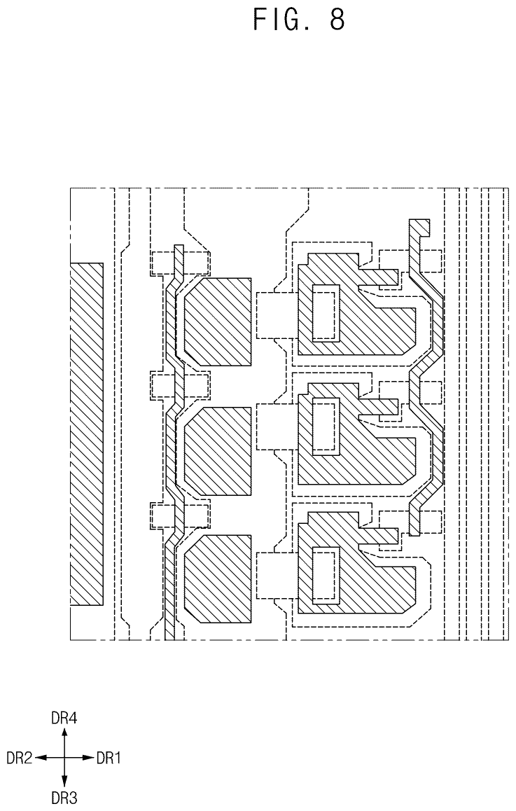

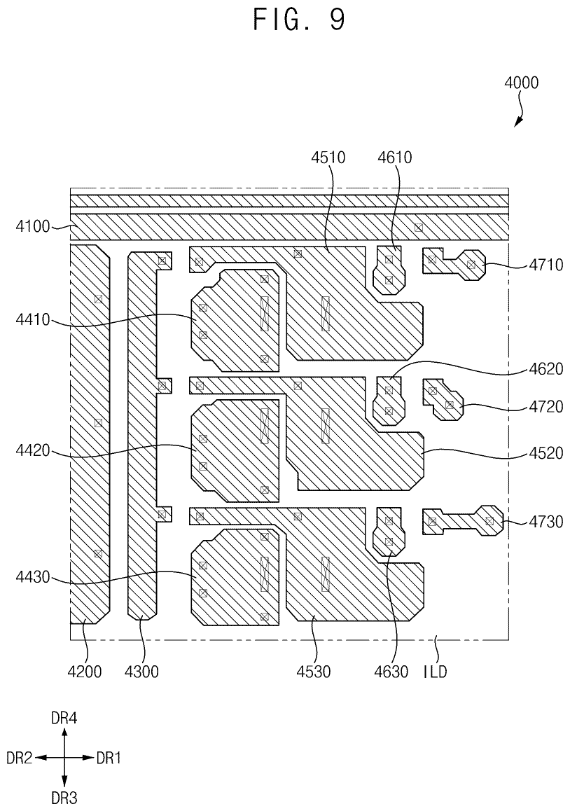

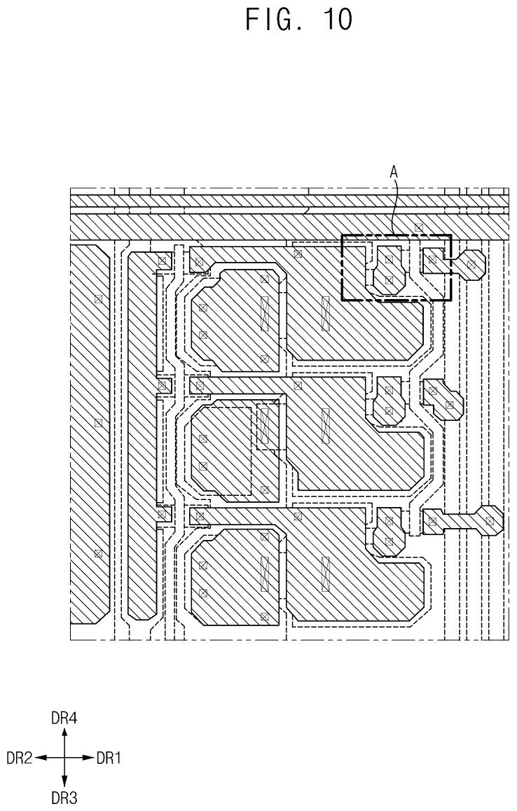

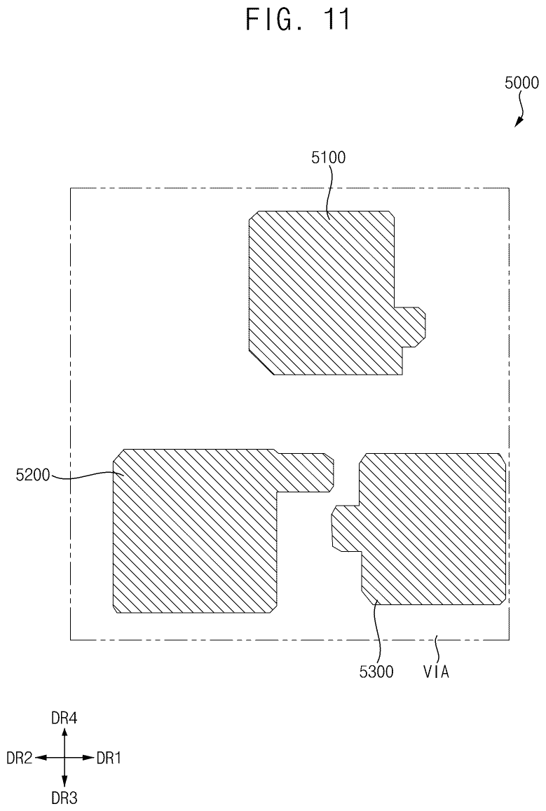

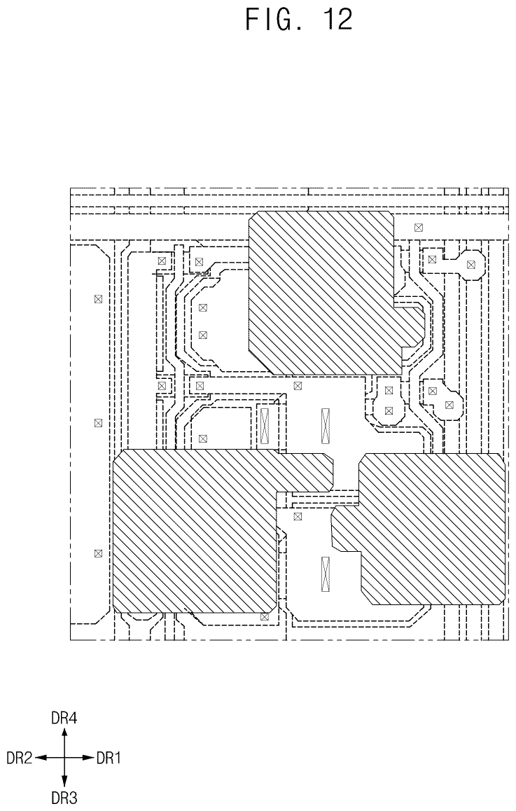

Specifically, FIG. 4 is a layout view illustrating a first conductive pattern. FIG. 5 is a layout view illustrating a semiconductor pattern. FIG. 6 is a layout view in which the semiconductor pattern is stacked on the first conductive pattern. FIG. 7 is a layout view illustrating a second conductive pattern. FIG. 8 is a layout view in which the second conductive pattern is stacked on the semiconductor pattern. FIG. 9 is a layout view illustrating the third conductive pattern. FIG. 10 is a layout view in which the third conductive pattern is stacked on the second conductive pattern. FIG. 11 is a layout view illustrating a fourth conductive pattern, and FIG. 12 is a layout view in which the fourth conductive pattern is stacked on the third conductive pattern.

Hereinafter, with reference to FIGS. 2 and 4 to 12, a layer-by-layer structure of the pixel PX included in the display device DD will be described. The pixel PX included in the display device DD may include a first conductive pattern 1000, an active pattern 2000, a second conductive pattern 3000, a third conductive pattern 4000, and a fourth conductive pattern 5000.

Referring to FIGS. 2 and 4, the first conductive pattern 1000 may be disposed on a substrate SUB. The first conductive pattern 1000 may include a common voltage line 1100, an initialization voltage line 1200, a driving voltage line 1300, a first lower electrode 1410, a second lower electrode 1420, a third lower electrode 1430, the first data line 1510, the second data line 1520, and the third data line 1530.

The substrate SUB may include a transparent or opaque material. In an embodiment of the present invention, examples of materials that can be used as the substrate SUB may include glass, quartz, and plastic. These can be used alone or in combination with each other.

The common voltage line 1100 may be disposed on the substrate SUB and may extend in the third direction DR3 and the fourth direction DR4. The common voltage line 1100 may provide the common voltage ELVSS to the first to third sub-pixels SPX1, SPX2, and SPX3.

The initialization voltage line 1200 may be disposed on the substrate SUB and may extend in the third direction DR3 and the fourth direction DR4. The initialization voltage line 1200 may be spaced apart from the common voltage line 1100 and may provide the initialization voltage VINT to the first to third sub-pixels SPX1, SPX2, and SPX3.

The driving voltage line 1300 may be disposed on the substrate SUB and may extend in the third direction DR3 and the fourth direction DR4. The driving voltage line 1300 may be spaced apart from the initialization voltage line 1200 and the common voltage line 1100 and may provide the driving voltage ELVDD to the first to third sub-pixels SPX1, SPX2, and SPX3.

The first lower electrode 1410 may be disposed on the substrate SUB and may be spaced apart from the driving voltage line 1300. In an embodiment of the present invention, the first lower electrode 1410 may be electrically connected to the initialization voltage line 1200. For example, the first lower electrode 1410 may correspond to the second terminal of the storage capacitor CST that is included in the first sub-pixel SPX1 described with reference to FIG. 3.

Additionally, the second lower electrode 1420 may be spaced apart from the first lower electrode 1410 and may correspond to a second terminal of a storage capacitor that is included in the second sub-pixel SPX2. The third lower electrode 1430 may be spaced apart from the second lower electrode 1420 and the first lower electrode 1410 and may correspond to a second terminal of a storage capacitor that is included in the third sub-pixel SPX3. For example, the second lower electrode 1420 may be disposed between the first lower electrode 1410 and the third lower electrode 1430.

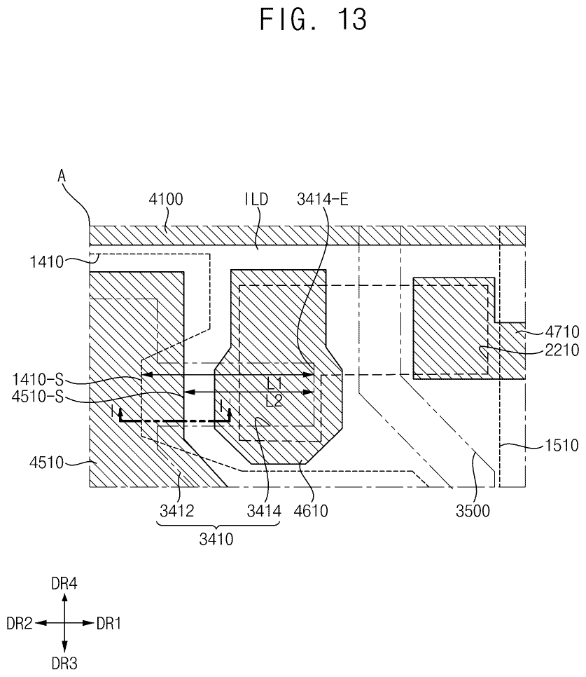

In addition, the first lower electrode 1410, the second lower electrode 1420, and the third lower electrode 1430 may have substantially the same planar profile (e.g., shape) as each other. A planar profile of each of the first lower electrode 1410, the second lower electrode 1420, and the third lower electrode 1430 will be described in more detail later with reference to FIG. 13.

The first data line 1510 may be disposed on the substrate SUB and may extend in the third direction DR3 and the fourth direction DR4. The first data line 1510 may provide the data voltage DATA to the second sub-pixel SPX2.

Additionally, the second data line 1520 may be spaced apart from the first data line 1510 and may provide the data voltage DATA to the first sub-pixel SPX1. The third data line 1530 may be spaced apart from the second data line 1520 and may provide the data voltage DATA to the third sub-pixel SPX3.

However, a connection relationship between the first to third data lines 1510, 1520, and 1530 and the first to third sub-pixels SPX1, SPX2, and SPX3 is not limited thereto. A connection relationship between the first to third data lines 1510, 1520, and 1530 and the first to third sub-pixels SPX1, SPX2, and SPX3 may be appropriately set as needed.

In an embodiment of the present invention, the first conductive pattern 1000 may be formed of metal, alloy, conductive metal oxide, transparent conductive material, or the like. For example, the first conductive pattern 1000 may include silver (Ag), an alloy including silver, molybdenum (Mo), an alloy including molybdenum, aluminum (Al), an alloy including aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These can be used alone or in combination with each other. Additionally, the first conductive pattern 1000 may be composed of a single layer or multiple layers.

Referring to FIGS. 2, 5, and 6, a buffer layer BFR may be disposed on the first conductive pattern 1000 and cover the first conductive pattern 1000. The buffer layer BFR may prevent metal atoms or impurities from diffusing into the semiconductor pattern 2000 from the substrate SUB. Additionally, the buffer layer BFR may control a rate of heat provision during a crystallization process for forming the semiconductor pattern 2000.

The semiconductor pattern 2000 may be disposed on the buffer layer BFR, and include a first active pattern 2110, a second active pattern 2120, a third active pattern 2130, a fourth active pattern 2210, a fifth active pattern 2220, a sixth active pattern 2230, a seventh active pattern 2310, an eighth active pattern 2320, and a ninth active pattern 2330.

In an embodiment of the present invention, the first active pattern 2110, the second active pattern 2120, the third active pattern 2130, the fourth active pattern 2210, the fifth active pattern 2220, the sixth active pattern 2230, the seventh active pattern 2310, the eighth active pattern 2320, and the ninth active pattern 2330 may be spaced apart from one another.

The first active pattern 2110, the second active pattern 2120, and the third active pattern 2130 may be arranged along the third direction DR3 (or the fourth direction DR4), may overlap with the first lower electrode 1410, the second lower electrode 1420, and the third lower electrode 1430, respectively.

In an embodiment of the present invention, the first active pattern 2110 may be electrically connected to the driving voltage line 1300 and transmit the driving voltage ELVDD to the first sub-pixel SPX1. For example, the first active pattern 2110 may correspond to the first terminal and the second terminal of the first transistor T1 that are included in the first sub-pixel SPX1.

Additionally, the second active pattern 2120 may be electrically connected to the driving voltage line 1300 and transmit the driving voltage ELVDD to the second sub-pixel SPX2. The third active pattern 2130 may be electrically connected to the driving voltage line 1300 and transmit the driving voltage ELVDD to the third sub-pixel SPX3.

The fourth active pattern 2210, the fifth active pattern 2220, and the sixth active pattern 2230 may be arranged along the third direction DR3 (or the fourth direction DR4).

In an embodiment of the present invention, the fourth active pattern 2210 may be electrically connected to the second data line 1520 and transmit the data voltage DATA to the first sub-pixel SPX1. For example, the fourth active pattern 2210 may correspond to the first terminal and the second terminal of the second transistor T2 that is included in the first sub-pixel SPX1.

Additionally, the fifth active pattern 2220 may be electrically connected to the first data line 1510 and transmit the data voltage DATA to the second sub-pixel SPX2. The sixth active pattern 2230 may be electrically connected to the third data line 1530 and transmit the data voltage DATA to the third sub-pixel SPX3.

The seventh active pattern 2310, the eighth active pattern 2320, and the ninth active pattern 2330 may be arranged along the third direction DR3 (or the fourth direction DR4), may overlap with the initialization voltage line 1200.

In an embodiment of the present invention, the seventh active pattern 2310 may be electrically connected to the initialization voltage line 1200 and transmit the initialization voltage VINT to the first sub-pixel SPX1. For example, the seventh active pattern 2310 may correspond to the first terminal and the second terminal of the third transistor T3 that is included in the first sub-pixel SPX1.

Additionally, the eighth active pattern 2320 may be electrically connected to the initialization voltage line 1200 and transmit the initialization voltage VINT to the second sub-pixel SPX2. The ninth active pattern 2330 may be electrically connected to the initialization voltage line 1200 and transmit the initialization voltage VINT to the third sub-pixel SPX3.

In an embodiment of the present invention, the semiconductor pattern 2000 may be formed of a silicon semiconductor material or an oxide semiconductor material. Examples of the silicon semiconductor material that can be used as the semiconductor pattern 2000 may include amorphous silicon, polycrystalline silicon, or the like. Examples of the oxide semiconductor material that can be used as the semiconductor pattern 2000 may include IGZO (InGaZnO), ITZO (InSnZnO), or the like. These can be used alone or in combination with each other.

Referring to FIGS. 2, 7, and 8, a gate insulating layer GI may be disposed on the semiconductor pattern 2000 and cover the semiconductor pattern 2000. In an embodiment of the present invention, the gate insulating layer GI may be formed of an insulating material. Examples of insulating materials that can be used as the gate insulating layer GI may include silicon oxide, silicon nitride, silicon oxynitride, or the like. These can be used alone or in combination with each other.

The second conductive pattern 3000 may be disposed on the gate insulating layer GI, and include a first double pattern 3100, a first gate line 3200, a second double pattern 3310, a third double pattern 3320, a fourth double pattern 3330, a first gate electrode 3410, a second gate electrode 3420, a third gate electrode 3430, and a second gate line 3500.

The first double pattern 3100 may overlap the common voltage line 1100 and may extend in the third direction DR3 (or the fourth direction DR4). The first double pattern 3100 may be electrically connected to the common voltage line 1100. The first double pattern 3100 may reduce an electrical resistance of the common voltage line 1100. Accordingly, a voltage drop of the common voltage ELVSS may be prevented.

The first gate line 3200 may extend in the third direction DR3 (or the fourth direction DR4), and overlap with the seventh active pattern 2310, the eighth active pattern 2320, and the ninth active pattern 2330. The first gate line 3200 may provide the second scan signal SS to the first sub-pixel SPX1, the second sub-pixel SPX2, and the third sub-pixel SPX3.

The second double pattern 3310, the third double pattern 3320, and the fourth double pattern 3330 may be arranged in the third direction DR3 (or the fourth direction DR4), and overlap with the driving voltage line 1300. The second double pattern 3310, the third double pattern 3320, and the fourth double pattern 3330 may be electrically connected to the driving voltage line 1300, and reduce an electrical resistance of the driving voltage line 1300. Accordingly, a voltage drop of the driving voltage ELVDD may be prevented.

The first gate electrode 3410, the second gate electrode 3420, and the third gate electrode 3430 may be arranged in the third direction DR3 (or the fourth direction DR4).

In an embodiment of the present invention, the first gate electrode 3410 may electrically connected to the fourth active pattern 2210 and overlap the first active pattern 2210. Accordingly, the first gate electrode 3410 may correspond to the gate terminal of the first transistor T1 that is included in the first sub-pixel SPX1.

Additionally, the second gate electrode 3420 may be electrically connected to the fifth active pattern 2220 and overlap the second active pattern 2120. The third gate electrode 3430 may be electrically connected to the sixth active pattern 2230 and overlap the third active pattern 2130.

The first gate electrode 3410 may include a first body part 3412 and a first protrusion part 3414. The first body part 3412 may overlap the first active pattern 1110 in a plan view. For example, the first gate electrode 3410 (e.g., the first body part 3412) may correspond to the gate terminal of the first transistor T1 that is included in the first sub-pixel SPX1. Additionally, the first body part 3412 may overlap the first lower electrode 1410 in a plan view. For example, the first gate electrode 3410 (e.g., the first body part 3412) may correspond to the first terminal of the storage capacitor CST that is included in the first sub-pixel SPX1.

The first protrusion part 3414 may protrude from the first body part 3412 in the first direction DR1. For example, the first protrusion part 3414 may protrude from the first body part 3412 toward the fourth active pattern 2210.

In an embodiment of the present invention, the first protrusion part 3414 may be entirely spaced apart from the first lower electrode 1410 in a plan view. For example, the first lower electrode 1410 may have a shape which does not overlap the first protrusion part 3414 in a plan view. This will be described in more detail later with reference to FIG. 13.

In addition, the first body part 3412 and the first protrusion part 3414 may be integrated with each other. For example, the first body part 3412 and the first protrusion part 3414 may be a single body. For example, the first body part 3412 and the first protrusion part 3414 may be formed integrally and connected to each other without forming an interface therebetween.

The second gate electrode 3420 may include a second body part 3422 and a second protrusion part 3424. The second body part 3422 may overlap the second active pattern 1120 in a plan view. For example, the second gate electrode 3420 (e.g., the second body part 3422) may correspond to a gate terminal of a first transistor included in the second sub-pixel SPX2. Additionally, the second body part 3422 may overlap the second lower electrode 1420 in a plan view. For example, the second gate electrode 3420 (e.g., the second body part 3422) may correspond to a first terminal of a storage capacitor that is included in the second sub-pixel SPX2.

The second protrusion part 3424 may protrude from the second body part 3422 in the first direction DR1. For example, the second protrusion part 3424 may protrude from the second body part 3422 toward the fifth active pattern 2220. In an embodiment of the present invention, the second protrusion part 3424 may be entirely spaced apart from the second lower electrode 1420 in a plan view. For example, the second lower electrode 1420 may have a shape which does not overlap the second protrusion part 3424 in a plan view.

In addition, the second body part 3422 and the second protrusion part 3424 may be integrated with each other. For example, the second body part 3422 and the second protrusion part 3424 may be a single body. For example, the second body part 3422 and the second protrusion part 3424 may be formed integrally and connected to each other without forming an interface therebetween.

The third gate electrode 3430 may include a third body part 3432 and a third protrusion part 3434. The third body part 3432 may overlap the third active pattern 1130 in a plan view. For example, the third gate electrode 3430 (e.g., the third body part 3432) may correspond to a gate terminal of a first transistor that is included in the third sub-pixel SPX3. Additionally, the third body part 3432 may overlap the third lower electrode 1430 in a plan view. For example, the third gate electrode 3430 (e.g., the third body part 3432) may correspond to a first terminal of a storage capacitor that is included in the third sub-pixel SPX3.

The third protrusion part 3434 may protrude from the third body part 3432 in the first direction DR1. For example, the third protrusion part 3434 may protrude from the third body part 3432 toward the sixth active pattern 2230. In an embodiment of the present invention, the third protrusion part 3434 may be entirely spaced apart from the third lower electrode 1430 in a plan view. For example, the third lower electrode 1430 may have a shape which does not overlap the third protrusion part 3434 in a plan view.

In addition, the first gate electrode 3410, the second gate electrode 3420, and the third gate electrode 3430 may have substantially the same planar profile (shape) as each other. For example, the first body part 3412, the second body part 3422, and the third body part 3432 may have substantially the same planar profile as each other, and the first protrusion part 3414, the second protrusion part 3424 and the third protrusion part 3434 may have substantially the same planar profile as each other. A planar profile of each of the first gate electrode 3410, the second gate electrode 3420, and the third gate electrode 3430 will be described in more detail later with reference to FIG. 13.

The gate line 3500 may extend in the third direction DR3 (or the fourth direction DR4), and overlap with the fourth active pattern 2210, the fifth active pattern 2220, and the fourth active pattern 2230. The gate line 3500 may provide the first scan signal SC to the first sub-pixel SPX1, the second sub-pixel SPX2, and the third sub-pixel SPX3. For example, the gate line 3500 may correspond to the gate terminal of the second transistor T2 described with reference to FIG. 3.

The second conductive pattern 3000 may be formed of metal, alloy, conductive metal oxide, transparent conductive material, or the like. For example, the second conductive pattern 3000 may include silver (Ag), an alloy containing silver, molybdenum (Mo), an alloy including molybdenum, and aluminum (Al), an alloy including aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These can be used alone or in combination with each other. Additionally, the second conductive pattern 3000 may be composed of a single layer or multiple layers.

Referring to FIGS. 2, 9, and 10, an interlayer insulating layer ILD may be disposed on the second conductive pattern 3000 and cover the second conductive pattern 3000. In an embodiment of the present invention, the interlayer insulating layer ILD may be formed of an insulating material. For example, the interlayer insulating layer ILD may include silicon oxide, silicon nitride, silicon oxynitride, or the like. These can be used alone or in combination with each other. Additionally, the interlayer insulating layer ILD may be composed of a single layer or multiple layers.

The third conductive pattern 4000 may be disposed on the interlayer insulating layer ILD, and include a gate connection line 4100, a common voltage contact pattern 4200, an initialization voltage contact pattern 4300, a first driving voltage contact pattern 4410, a second driving voltage contact pattern 4420, a third driving voltage contact pattern 4430, a first connection pattern 4510, a second connection pattern 4520, a third connection pattern 4530, a fourth connection pattern 4610, a fifth connection pattern 4620, a sixth connection pattern 4630, a seventh connection pattern 4710, an eighth connection pattern 4720, and a ninth connection pattern 4730.

The gate connection line 4100 may extend in the first direction DR1 (or the second direction DR2). The gate connection line 4100 may contact the gate line 3500 through at least one contact hole. The gate connection line 4100 may transmit the first scan signal SC to the gate line 3500.

The common voltage contact pattern 4200 may overlap the common voltage line 1100 and the first double pattern 3100 and extend in the third direction DR3 (or the fourth direction DR4). The common voltage contact pattern 4200 may be connected to the common voltage line 1100 and the first double pattern 3100 through at least one contact hole.

The initialization voltage contact pattern 4300 may overlap the initialization voltage line 1200 and may extend in the third direction DR3 (or the fourth direction DR4). The initialization voltage contact pattern 4300 may be connected to the initialization voltage line 1200, the seventh active pattern 2310, the eighth active pattern 2320, and the ninth active pattern 2330 through at least one contact hole. The initialization voltage contact pattern 4300 may transmit the initialization voltage VINT from the initialization voltage line 1200 to the seventh to ninth active patterns 2310, 2320, and 2330.

The first driving voltage contact pattern 4410, the second driving voltage contact pattern 4420, and the third driving voltage contact pattern 4430 may be arranged in the third direction DR3 (or in the fourth direction DR4).

The first driving voltage contact pattern 4410 may be connected to the driving voltage line 1300, the first active pattern 2110, and the second double pattern 3310 through at least one contact hole. The first driving voltage contact pattern 4410 may transmit the driving voltage ELVDD from the driving voltage line 1300 to the first active pattern 2110.

The second driving voltage contact pattern 4420 may be connected to the driving voltage line 1300, the second active pattern 2120, and the third double pattern 3320 through at least one contact hole. The second driving voltage contact pattern 4420 may transmit the driving voltage ELVDD from the driving voltage line 1300 to the second active pattern 2120.

The third driving voltage contact pattern 4430 may be connected to the driving voltage line 1300, the third active pattern 2130, and the fourth double pattern 3330 through at least one contact hole. The third driving voltage contact pattern 4430 may transmit the driving voltage ELVDD from the driving voltage line 1300 to the third active pattern 2130.

The first connection pattern 4510, the second connection pattern 4520, and the third connection pattern 4530 may be arranged in the third direction DR3 (or the fourth direction DR4).

The first connection pattern 4510 may be connected to the first lower electrode 1410, the seventh active pattern 2310, and the first active pattern 2110 through at least one contact hole. The first connection pattern 4510 may transmit the initialization voltage VINT from the seventh active pattern 2310 to the first lower electrode 1410.

The second connection pattern 4520 may be connected to the second lower electrode 1420, the eighth active pattern 2320, and the second active pattern 2120 through at least one contact hole. The second connection pattern 4520 may transmit the initialization voltage VINT from the eighth active pattern 2320 to the second lower electrode 1420.

The third connection pattern 4530 may be connected to the third lower electrode 1430, the ninth active pattern 2330, and the third active pattern 2130 through at least one contact hole. The third connection pattern 4530 may transmit the initialization voltage VINT from the ninth active pattern 2330 to the third lower electrode 1430.

The first connection pattern 4510 may overlap at least a portion of the first protrusion part 3414 of the first gate electrode 3410 in a plan view. For example, the first connection pattern 4510 may cover at least a portion of the first protrusion part 3414 of the first gate electrode 3410 in a plan view. In an embodiment of the present invention, a portion of the first connection pattern 4510 which overlaps the first protrusion part 3414 might not overlap the first lower electrode 1410 in a plan view. For example, as the first lower electrode 1410 has a shape which is entirely spaced apart from the first protrusion part 3414 in a plan view, the portion of the first connection pattern 4510 which overlaps the first protrusion part 3414 may be spaced apart from the first lower electrode 1410 in a plan view. This will be described in more detail later with reference to FIG. 13.

In addition, the first connection pattern 4510 may be spaced apart from at least a portion of the first protrusion part 3414 of the first gate electrode 3410. For example, the first connection pattern 4510 may partially overlap the first protrusion part 3414. However, the present invention is not necessarily limited thereto.

Additionally, the second connection pattern 4520 may overlap at least a portion of the second protrusion part 3424 of the second gate electrode 3420 in a plan view. Additionally, the third connection pattern 4530 may overlap at least a portion of the third protrusion part 3434 of the third gate electrode 3430 in a plan view.

In addition, the first connection pattern 4510, the second connection pattern 4520, and the third connection pattern 4530 may have substantially the same planar profile (shape) as each other. A planar profile of each of the first connection pattern 4510, the second connection pattern 4520, and the third connection pattern 4530 will be described in more detail later with reference to FIG. 13.

The fourth connection pattern 4610, the fifth connection pattern 4620, and the sixth connection pattern 4630 may be arranged in the third direction DR3 (or the fourth direction DR4).

The fourth connection pattern 4610 may overlap the fourth active pattern 2210 and the first gate electrode 3410. Additionally, the fourth connection pattern 4610 may be connected to the fourth active pattern 2210 and the first gate electrode 3410 through at least one contact hole. For example, the fourth connection pattern 4610 may overlap the fourth active pattern 2210 and the first protrusion part 3414, and contact the fourth active pattern 2210 and the first protrusion part 3414. For example, the fourth connection pattern 4610 may connect the fourth active pattern 2210 and the first gate electrode 3410 to each other. Accordingly, the fourth connection pattern 4610 may transmit the data voltage DATA from the fourth active pattern 2210 to the first gate electrode 3410.

The fifth connection pattern 4620 may overlap the fifth active pattern 2220 and the second gate electrode 3420. Additionally, the fifth connection pattern 4620 may be connected to the fifth active pattern 2220 and the second gate electrode 3420 through at least one contact hole. For example, the fifth connection pattern 4620 may overlap the fifth active pattern 2220 and the second protrusion part 3424, and contact the fifth active pattern 2220 and the second protrusion part 3424. For example, the fifth connection pattern 4620 may connect the fifth active pattern 2220 and the second gate electrode 3420 to each other. Accordingly, the fifth connection pattern 4620 may transmit the data voltage DATA from the fifth active pattern 2220 to the second gate electrode 3420.

The sixth connection pattern 4630 may overlap the sixth active pattern 2230 and the third gate electrode 3430. Additionally, the sixth connection pattern 4630 may be connected to the sixth active pattern 2230 and the third gate electrode 3430 through at least one contact hole. For example, the sixth connection pattern 4630 may overlap the sixth active pattern 2230 and the third protrusion part 3434, and contact the sixth active pattern 2230 and the third protrusion part 3434. For example, the sixth connection pattern 4630 may connect the sixth active pattern 2230 and the third gate electrode 3430 to each other. Accordingly, the sixth connection pattern 4630 can transmit the data voltage DATA from the sixth active pattern 2230 to the third gate electrode 3430.

The seventh connection pattern 4710, the eighth connection pattern 4720, and the ninth connection pattern 4730 may be arranged in the third direction DR3 (or the fourth direction DR4).

The seventh connection pattern 4710 may be connected to the second data line 1520 and the fourth active pattern 2210 through at least one contact hole. For example, the seventh connection pattern 4710 may connect the second data line 1520 and the fourth active pattern 2210 to each other. Accordingly, the seventh connection pattern 4710 may transmit the data voltage DATA from the second data line 1520 to the fourth active pattern 2210.

The eighth connection pattern 4720 may be connected to the first data line 1510 and the fifth active pattern 2220 through at least one contact hole. For example, the eighth connection pattern 4720 may connect the first data line 1510 and the fifth active pattern 2220 to each other. Accordingly, the eighth connection pattern 4720 can transmit the data voltage DATA from the first data line 1510 to the fifth active pattern 2220.

The ninth connection pattern 4730 may be connected to the third data line 1530 and the sixth active pattern 2230 through at least one contact hole. For example, the ninth connection pattern 4730 may connect the third data line 1530 and the sixth active pattern 2230 to each other. Accordingly, the ninth connection pattern 4730 may transmit the data voltage DATA from the third data line 1530 to the sixth active pattern 2230.

The third conductive pattern 4000 may be formed of metal, alloy, conductive metal oxide, transparent conductive material, or the like. For example, the third conductive pattern 4000 may include silver (Ag), an alloy containing silver, molybdenum (Mo), an alloy including molybdenum, aluminum (Al), an alloy including aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These can be used alone or in combination with each other. Additionally, the third conductive pattern 4000 may be composed of a single layer or multiple layers.

Referring to FIGS. 2, 11, and 12, a via insulating layer VIA may be disposed on the third conductive pattern 4000 and cover the third conductive pattern 4000. The via insulating layer VIA may be formed of an insulating material. For example, the via insulating layer VIA may include photoresist, polyacrylic resin, polyimide resin, acrylic resin, or the like.

The fourth conductive pattern 5000 may be disposed on the via insulating layer VIA and may include a first pixel electrode 5100, a second pixel electrode 5200, and a third pixel electrode 5300.

The first pixel electrode 5100 may be connected to the first connection pattern 4510 through at least one contact hole. The first pixel electrode 5100 may receive the initialization voltage VINT or the driving current through the first connection pattern 4510. The second pixel electrode 5200 may be connected to the second connection pattern 4520 through at least one contact hole. The second pixel electrode 5200 may receive the initialization voltage VINT or the driving current through the second connection pattern 4520. The third pixel electrode 5300 may be connected to the third connection pattern 4530 through at least one contact hole. The third pixel electrode 5300 may receive the initialization voltage VINT or the driving current through the third connection pattern 4530.

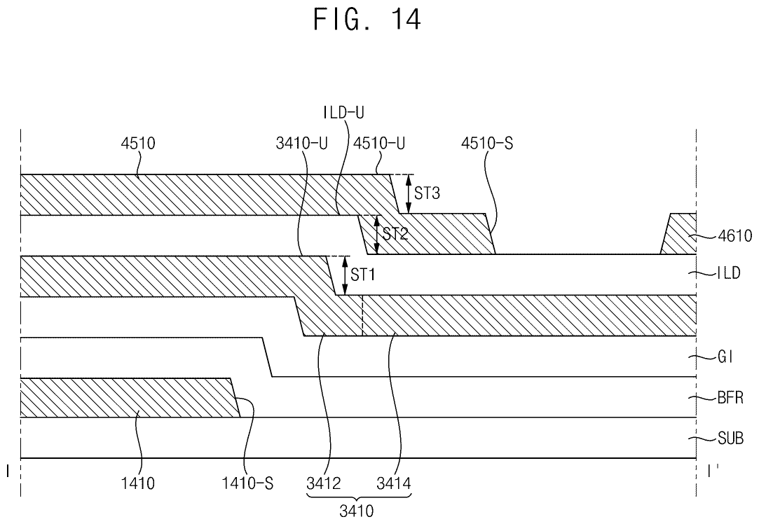

FIG. 13 is an enlarged view of area A of FIG. 10, and FIG. 14 is a cross-sectional view taken along line I-I′ of FIG. 13.

In FIG. 13, for convenience of description, the third conductive pattern 4000 and components below the interlayer insulating layer ILD are also illustrated, and contact holes are omitted.

Referring to FIGS. 10, 13, and 14, the first lower electrode 1410 may have a first side 1410-S adjacent to an end 3414-E of the first protrusion part 3414 of the first gate electrode 3410 in the second direction DR2. The first side 1410-S may be one of several sides defining a planar profile (shape) of the first lower electrode 1410.

The first side 1410-S may be depressed more toward the inside of the first lower electrode 1410 than other sides of the first lower electrode 1410. For example, the first side 1410-S may be indented with respect to the other sides of the first lower electrode 1410 facing the first direction DR1. For example, the first lower electrode 1410 may have a planar profile (shape) in which a portion corresponding to the first protrusion part 3414 is locally depressed, and accordingly, the first side 1410-S may be defined.

The first side 1410-S of the first lower electrode 1410 may overlap the first connection pattern 4510 in a plan view and may be covered by the first connection pattern 4510.

For example, the first connection pattern 4510 may have a second side 4510-S adjacent to the end 3414-E of the first protrusion part 3414 in the second direction DR2, and the second side 4510-S may be closer to the end 3414-E of the first protrusion part 3414 than the first side 1410-S of the first lower electrode 1410. The second side 4510-S may be one of several sides defining a planar profile (shape) of the first connection pattern 4510.

For example, the first lower electrode 1410 may have a planar profile (shape) in which a portion corresponding to the first protrusion part 3414 is locally depressed, and accordingly, the first side 1410-S may be defined at a position farther from the end 3414-E of the first protrusion 3414 in the second direction DR2 than the second side 4510-S.

For example, the second side 4510-S of the first connection pattern 4510 may be spaced apart from the first side 1410-S of the first lower electrode 1410 in the first direction DR1. For example, the shortest distance L1 in the second direction DR2 from the end 3414-E of the first protrusion 3414 to the first side 1410-S of the first lower electrode 1410 may be greater than the shortest distance L2 in the second direction DR2 from the end 3414-E of the first protrusion part 3414 to the second side 4510-S of the first connection pattern 4510. As a result, in a plan view, the first side 1410-S, the second side 4510-S, and the end 3414-E of the first protrusion part 3414 may be arranged sequentially in the first direction DR1.

In an embodiment of the present invention, the first side 1410-S of the first lower electrode 1410 may overlap the first body part 3412 of the first gate electrode 3410 in a plan view, and may be covered by the first body part 3412. For example, the first lower electrode 1410 may have a planar profile (shape) in which a portion corresponding to the first protrusion part 3414 is locally depressed so as to be entirely spaced apart from the first protrusion part 3414 in a plan view. Accordingly, the first side 1410-S may overlap the first body part 3412 and be covered by the first body part 3412.

As illustrated in FIG. 14, an upper surface 3410-U of the first gate electrode 3410 may have a first step ST1 due to the first lower electrode 1410. For example, an upper surface of the buffer layer BFR and an upper surface of the gate insulating layer GI may have a step due to the first side 1410-S of the first lower electrode 1410, and accordingly, the upper surface 3410-U of the first gate electrode 3410 may have the first step ST1.

In an embodiment of the present invention, the first step ST1 may be defined in the first body part 3412 of the first gate electrode 3410. For example, as the first side 1410-S of the first lower electrode 1410 overlaps the first body part 3412, the step ST1 formed by the first side 1410-S may be defined in the first body part 3412 of the first gate electrode 3410.

An upper surface ILD-U of the interlayer insulating layer ILD may have a second step ST2 due to the first step ST1. Additionally, an upper surface 4510-U of the first connection pattern 4510 may have a third step ST3 due to the second step ST2. For example, the first step ST1, the second step ST2, and the third step ST3 may be defined in series by the first side 1410-S of the first lower electrode 1410.

The first connection pattern 4510 may cover a portion of the interlayer insulating layer ILD where the second step ST2 is defined. For example, the first connection pattern 4510 may be formed so that the second side 4510-S is closer to the end 3414-E of the first protrusion part 3414 than the first side 1410-S of the first lower electrode 1410. Accordingly, the first connection pattern 4510 may cover the portion of the interlayer insulating layer ILD where the second step ST2 is defined due to the first side 1410-S. For example, the first connection pattern 4510 may cover the portion of the interlayer insulating layer ILD where the second step ST2 is defined and a portion adjacent to the portion where the second step ST2 is defined.

A void or seam may occur in the portion of the interlayer insulating layer ILD where the second step ST2 is defined, and deterioration of the display device DD may occur as impurities, moisture, oxygen, or the like flow through the void or the seam. For example, an etching material used in a process after forming the interlayer insulating layer ILD may flow through the void or the seam, and accordingly, a reliability of the display device DD may deteriorate due to deterioration of the interlayer insulating layer ILD or components that are below the interlayer insulating layer ILD.

According to embodiments of the present invention, the first lower electrode 1410 may have a planar profile (shape) in which a portion corresponding to the first protrusion part 3414 is locally depressed, and accordingly, have the first side 1410-S. Additionally, the first connection pattern 4510 may cover the first side 1410-S. For example, the first connection pattern 4510 may have the second side 4510-S closer to the end 3414-E of the first protrusion part 3414 than the first side 1410-S of the first lower electrode 1410.

Accordingly, the first connection pattern 4510 may cover the portion of the interlayer insulating layer ILD where the second step ST2 is defined due to the first side 1410-S. Accordingly, an inflow of impurities, moisture, oxygen, or the like through the portion of the interlayer insulating layer ILD where the second step ST2 is defined may be reduced or prevented. Accordingly, deterioration of the interlayer insulating layer ILD or components below the interlayer insulating layer ILD may be prevented. Accordingly, the reliability of the display device DD may be increased.

Meanwhile, a planar profile (shape) of the first lower electrode 1410 illustrated in FIGS. 4 and 13 is only an example, and the present invention is not necessarily limited thereto. For example, if the first lower electrode 1410 has the first side 1410-S as a portion of the first lower electrode 1410 corresponding to the first protrusion part 3414 is locally depressed, a planar profile of the first lower electrode 1410 may be modified in various ways as needed.

In addition, as described above, a planar profile (shape) of each of the second lower electrode 1420 and the third lower electrode 1430 may be substantially the same as a planar profile of the first lower electrode 1410. A planar profile of each of the second gate electrode 3420 and the third gate electrode 3430 may be substantially the same as a planar profile of the first gate electrode 3410, and a planar profile of each of the second connection pattern 4520 and the third connection pattern 4530 may be substantially the same as a planar profile of the first connection pattern 4510. Therefore, a relationship between the first lower electrode 1410, the first gate electrode 3410, and the first connection pattern 4510 described with reference to FIGS. 13 and 14 may be equally applied throughout the specification. Therefore, redundant descriptions are omitted.

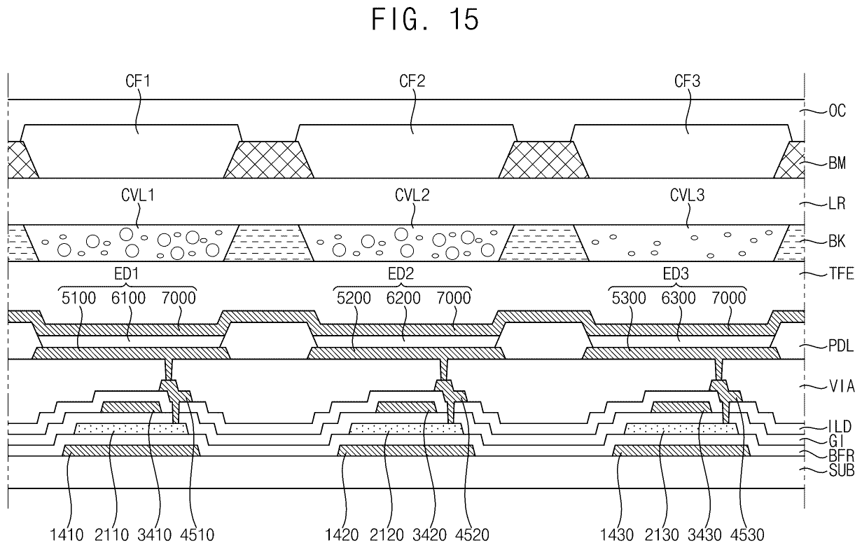

FIG. 15 is a cross-sectional view illustrating the display device of FIG. 1.

Referring to FIG. 15, the display device DD may include the substrate SUB, the first to third lower electrodes 1410, 1420, 1430, the first to third active patterns 2110, 2120, 2130, the first to third gate electrodes 3410, 3420, 3430, the first to third connection patterns 4510, 4520, 4530, the first to third pixel electrodes 5100, 5200, 5300 a first light emitting layer 6100, a second light emitting layer 6200, a third light emitting layer 6300, a common electrode 7000, an encapsulation layer TFE, a bank layer BK, a first color conversion layer CVL1, a second color conversion layer CVL2, a third color conversion layer CVL3, a refractive layer LR, a light blocking layer BM, a first color filter CF1, a second color filter CF2, a third color filter CF3, and a planarization layer OC. Hereinafter, overlapping descriptions will be omitted.

A pixel defining layer PDL may be disposed on the via insulating layer VIA. The pixel defining layer PDL may be formed of an insulating material. For example, the pixel defining layer PDL may include photoresist, polyacrylic resin, polyimide resin, acrylic resin, or the like. These materials can be used alone or in combination with each other.

Openings that expose the first pixel electrode 5100, the second pixel electrode 5200, and the third pixel electrode 5300 may be formed in the pixel defining layer PDL.

The first light emitting layer 6100 may be disposed on the first pixel electrode 5100. The second light emitting layer 6200 may be disposed on the second pixel electrode 5200, and the third light emitting layer 6300 may be disposed on the third pixel electrode 5300. The first light emitting layer 6100, the second light emitting layer 6200, and the third light emitting layer 6300 may be formed of organic materials and emit light of a preset color. For example, the first light emitting layer 6100, the second light emitting layer 6200, and the third light emitting layer 6300 may emit blue light. However, the present invention is not necessarily limited thereto. In addition, in FIG. 15, the first light emitting layer 6100, the second light emitting layer 6200, and the third light emitting layer 6300 are illustrated as not connected, but the present invention is not necessarily limited thereto. For example, the first light emitting layer 6100, the second light emitting layer 6200, and the third light emitting layer 6300 may be formed to be continuously connected to each other.

The common electrode 7000 may be disposed on the first to third light emitting layers 6100, 6200, 6300. The common electrode 7000 may be a plate electrode. In an embodiment of the present invention, the common voltage ELVSS of FIG. 2 may be provided to the common electrode 7000.

The first pixel electrode 5100, the first light emitting layer 6100, and the common electrode 7000 may form a first light emitting element ED1. For example, the first light emitting element ED1 may correspond to the light emitting element LED of FIG. 3. Additionally, the second pixel electrode 5200, the second light emitting layer 6200, and the common electrode 7000 may form a second light emitting element ED2. The third pixel electrode 5300, the third light emitting layer 6300, and the common electrode 7000 may form a third light emitting element ED3.

The encapsulation layer TFE may be disposed on the common electrode 7000. The encapsulation layer TFE may be formed of an insulating material. For example, the encapsulation layer TFE may have a structure in which inorganic layers and organic layers are alternately stacked on each other. The encapsulation layer TFE may prevent foreign substances from penetrating into the first to third light emitting elements ED1, ED2, ED3.

The bank layer BK may be disposed on the encapsulation layer TFE. The bank layer BK may be formed of a light blocking material and may block light that is emitted from a lower part. Additionally, an opening exposing the encapsulation layer TFE may be formed in the bank layer BK.

The first color conversion layer CVL1 may overlap the first light emitting layer 6100. In an embodiment of the present invention, the first color conversion layer CVL1 may convert a wavelength of light that is emitted from the first light emitting layer 6100. For example, the first color conversion layer CVL1 may include phosphors, scatterers, quantum dots, or the like. In an embodiment of the present invention, as light emitted from the first light emitting layer 6100 passes through the first color conversion layer CVL1, green light may be emitted.

The second color conversion layer CVL2 may overlap the second light emitting layer 6200. In an embodiment of the present invention, the second color conversion layer CVL2 may convert a wavelength of light that is emitted from the second light emitting layer 6200. For example, the second color conversion layer CVL2 may include phosphors, scatterers, quantum dots, or the like. In an embodiment of the present invention, as light emitted from the second light emitting layer 6200 passes through the second color conversion layer CVL2, red light may be emitted.

The third color conversion layer CVL3 may overlap the third light emitting layer 6300. In an embodiment of the present invention, the third color conversion layer CVL3 may scatter a wavelength of light that is emitted from the third light emitting layer 6300. For example, the third color conversion layer CVL3 may include a transparent polymer material, scatterers, or the like. In an embodiment of the present invention, as light emitted from the third light emitting layer 6300 passes through the third color conversion layer CVL3, blue light may be emitted.

In an embodiment of the present invention, the refractive layer LR may be disposed on the first to third color conversion layers CVL1, CVL2, CVL3. The refractive layer LR may have a predetermined refractive index that is different from that of adjacent layers. Accordingly, a light efficiency of the display device DD may be increased. In addition, in an embodiment of the present invention, the refractive layer LR may be disposed below the first to third color conversion layers CVL1, CVL2, CVL3. Additionally, in an embodiment of the present invention, the refractive layer LR may include first and second refractive layers, and the first refractive layer may be disposed on the first to third color conversion layers CVL1, CVL2, CVL3, and the second refractive layer may be disposed below the first to third color conversion layers CVL1, CVL2, CVL3.

The light blocking layer BM may be disposed on the refractive layer LR. The light blocking layer BM may be formed of a light blocking material and may block light that is emitted from a lower part. Additionally, an opening exposing the refractive layer LR may be formed in the light blocking layer BM.

The first color filter CF1 may overlap the first color conversion layer CVL1. In an embodiment of the present invention, the first color filter CF1 may transmit light of a wavelength corresponding to green light.

The second color filter CF2 may overlap the second color conversion layer CVL2. In an embodiment of the present invention, the second color filter CF2 may transmit light of a wavelength corresponding to red light.

The third color filter CF3 may overlap the third color conversion layer CVL3. In an embodiment of the present invention, the third color filter CF3 may transmit light of a wavelength corresponding to blue light.

The planarization layer OC may be disposed on the first to third color filters CF1, CF2, CF3. The planarization layer OC may be formed of an organic material and may provide a substantially flat upper surface.

In addition, a structure of the display device DD described with reference to FIG. 15 may change in various ways depending on embodiments, and is not necessarily limited thereto.

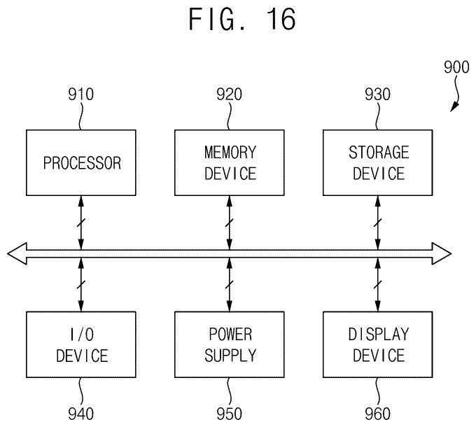

FIG. 16 is a block diagram illustrating an electronic device according to an embodiment of the present disclosure.

Referring to FIG. 16, in an embodiment, an electronic device 900 may include a processor 910, a memory device 920, a storage device 930, an input/output device 940, a power supply 950, and a display device 960. In this case, the display device 960 may correspond to the display device DD described with reference to FIGS. 1 to 15. The electronic device 900 may further include several ports capable of communicating with a video card, a sound card, a memory card, a USB device, and the like.

In an embodiment, the electronic device 900 may be implemented as a television. In another embodiment, the electronic device 900 may be implemented as a smart phone. However, the electronic device 900 is not limited thereto, and for example, the electronic device 900 may be implemented as a mobile phone, a video phone, a smart pad, a smart watch, a tablet PC, a vehicle navigation device, a computer monitor, a laptop computer, a head mounted display (HMD), and the like.

The processor 910 may perform certain calculations or tasks. The processor 910 may control the display device 960. In an embodiment, the processor 910 may be a microprocessor, a central processing unit (CPU), an application processor (AP), and/or the like. The processor 910 may be connected to other components through an address bus, a control bus, a data bus, and the like. The processor 910 may also be connected to an expansion bus, such as a peripheral component interconnect (PCI) bus.

The memory device 920 may store data necessary for the operation of the electronic device 900. For example, the memory device 920 may include an erasable programmable read-only memory (EPROM) device, an electrically erasable programmable read-only memory (EEPROM) device, a flash memory device, a phase change random access memory (PRAM) device, a resistance random access memory (RRAM) device, a nano floating GEe memory (NFGM) device, a polymer random access memory (PoRAM) device, a magnetic random access memory (MRAM) device, a non-volatile memory device such as a ferroelectric random access memory (FRAM) device and/or a volatile memory device such as a dynamic random access memory (DRAM) device, a static random access memory (SRAM) device, and a mobile DRAM device, and the like.

The storage device 930 may include a solid state drive (SSD), a hard disk drive (HDD), a CD-ROM, and the like.

The input/output device 940 may include input means such as a keyboard, keypad, touch pad, touch screen, mouse, and the like and output means such as a speaker, a printer, and the like.

The power supply 950 may supply power necessary for the operation of the electronic device 900. The display device 960 may be connected to other components through buses or other communication links. In an embodiment, the display device 960 may be included in the input/output device 940.

The present invention can be applied to, for example, a display panel inspection device of various display devices. For example, the present invention is applicable to a display panel inspection device of various display devices such as display devices for vehicles, ships and aircraft, portable communication devices, display devices for exhibition or information transmission, medical display devices, and the like.

While the present invention has been described with reference to embodiments thereof, it will be understood by those of ordinary skill in the art that various changes in form and details may be made thereto without departing from the spirit and scope of the present invention.

What is claimed is:

1. A display device comprising:
a first active pattern disposed on a substrate;
a gate electrode disposed on the first active pattern and including a body part and a protrusion part, wherein the body part overlaps the first active pattern in a plan view, and the protrusion part protrudes from the body part in a first direction;
a lower electrode disposed below the first active pattern and having a first side adjacent to an end of the protrusion part in a second direction opposite to the first direction; and
a first connection pattern disposed on the gate electrode, and in contact with the first active pattern, wherein the first connection pattern covers the first side of the lower electrode.

2. The display device of claim 1, wherein, in a plan view, the first connection pattern overlaps at least a portion of the protrusion part and is spaced apart from at least a portion of the protrusion part.

3. The display device of claim 1, wherein an upper surface of the gate electrode has a first step due to the lower electrode,
an upper surface of the insulating layer between the gate electrode and the first connection pattern has a second step due to the first step of the upper surface of the gate electrode, and
an upper surface of the first connection pattern has a third step due to the second step of the upper surface of the insulating layer.

4. The display device of claim 3, wherein the first connection pattern covers a portion of the insulating layer where the second step is formed.

5. The display device of claim 3, wherein the first step of the upper surface of the gate electrode is formed in the body part of the gate electrode.

6. The display device of claim 1, wherein the first connection pattern has a second side adjacent to the end of the protrusion part, and
the second side is closer to the end of the protrusion part than the first side of the lower electrode.

7. The display device of claim 6, wherein, in a plan view, the shortest distance in the second direction from the end of the protrusion part to the first side of the lower electrode is greater than the shortest distance in the second direction from the end of the protrusion part to the second side of the first connection pattern.

8. The display device of claim 6, wherein, in a plan view, the second side of the first connection pattern is spaced apart from the first side of the lower electrode in the first direction.

9. The display device of claim 1, wherein the lower electrode is spaced apart from the protrusion part in a plan view.

10. The display device of claim 1, further comprising:
a first transistor and a second transistor electrically connected to each other, and
wherein the first transistor includes the first active pattern and at least a portion of the gate electrode.

11. The display device of claim 10, further comprising:
a second active pattern spaced apart from the first active pattern; and
a gate line spaced apart from the gate electrode and disposed on the second active pattern, and
wherein the second transistor includes the second active pattern and at least a portion of the gate line.

12. The display device of claim 11, wherein the protrusion part protrudes toward the second active pattern.

13. The display device of claim 11, further comprising:
a second connection pattern connected the protrusion part and the second active pattern, and
wherein the second active pattern and the gate electrode are electrically connected to each other through the second connection pattern.

14. The display device of claim 13, further comprising:
a data line disposed on the substrate and electrically connected to the second active pattern; and
a third connection pattern connected to the second active pattern and the data line.

15. The display device of claim 10, further comprising:
a storage capacitor electrically connected to the first transistor, and
wherein the storage capacitor includes at least a portion of the lower electrode and at least a portion of the gate electrode.

16. The display device of claim 10, wherein the second transistor is a switching transistor which transmits a data voltage based on a switching operation, and
the first transistor is a driving transistor which generates a driving current corresponding to the data voltage.

17. The display device of claim 1, wherein the protrusion part and the body part are a single body.

18. A display device comprising:
a display panel including a plurality of sub-pixels;
a gate driver providing a gate signal to the display panel; and
a data driver providing a data voltage to the display panel, and
wherein each of the sub-pixels includes a first transistor, a second transistor, and a storage capacitor which are electrically connected to each other,
the first transistor includes a first active pattern and at least a portion of a gate electrode disposed on the first active pattern,
the second transistor includes a second active pattern and at least a portion of a gate line disposed on the second active pattern, wherein the second active pattern is spaced apart from the first active pattern,
the storage capacitor includes at least a portion of a lower electrode and at least a portion of the gate electrode, wherein the lower electrode is disposed below the first active pattern, and
the gate electrode includes a body part and a protrusion part, wherein the body part overlaps the first active pattern in a plan view, and the protrusion part protrudes from the body part in a first direction and is spaced apart from the lower electrode in a plan view.

19. The display device of claim 18, further comprising:
a first connection pattern disposed on the gate electrode and connected to the first active pattern; and
a second connection pattern disposed on a same layer as the first connection pattern and connected to the protrusion part and the second active pattern, and
wherein the first connection pattern overlaps at least a portion of the protrusion part and is spaced apart from at least a portion of the protrusion part, and
wherein the second active pattern and the gate electrode are electrically connected to each other through the second connection pattern.

20. The display device of claim 18, wherein the second transistor is a switching transistor which transmits a data voltage that is provided from the data driver based on a switching operation, and
the first transistor is a driving transistor which generates a driving current corresponding to the data voltage.

21. An electronic device comprising:
a display device; and
a processor which controls the display device,
wherein the display device includes:
a first active pattern disposed on a substrate;
a gate electrode disposed on the first active pattern and including a body part and a protrusion part, wherein the body part overlaps the first active pattern in a plan view, and the protrusion part protrudes from the body part in a first direction;
a lower electrode disposed below the first active pattern and having a first side adjacent to an end of the protrusion part in a second direction opposite to the first direction; and
a first connection pattern disposed on the gate electrode, and in contact with the first active pattern, wherein the first connection pattern covers the first side of the lower electrode.
